(19) United States
(12) Patent Application Publication
(10) Pub. No.: US 2011/0303439 A1
(43) Pub. Date: Dec. 15, 2011

(54) ADHESIVE RESIN COMPOSITIONS, AND LAMINATES AND FLEXIBLE PRINTED WIRING BOARDS USING SAME

(76) Inventors: Shingo Kaimori, Osaka (JP); Jun Sugawara, Osaka (JP); Akira Mizoguchi, Osaka (JP); Syougo Asai, Shiga (JP); Takuma Yoshisaka, Shiga (JP); Naota Uenishi, Shiga (JP)

(21) Appl. No.: 13/203,209

(22) PCT Filed: Jan. 18, 2010
(86) PCT No.: PCT/JP2010/050482

§ 371 Date: Aug. 24, 2011

(30) Foreign Application Priority Data
Feb. 24, 2009 (JP) 2009-040558

(51) Int. Cl. H05K 1/02; C09J 163/02; C09J 11/06; C09J 167/00; C09J 177/00; B32B 7/12; C09J 185/02

(52) U.S. Cl. 174/254; 428/355 EP; 523/435

(57) ABSTRACT

Provided are an adhesive composition that is halogen-free and that can satisfy flame retardancy without impairing adhesiveness or solder heat resistance, and a laminate and a flexible printed wiring board using the same. The adhesive resin composition contains an epoxy resin; a thermoplastic resin; a benzoxazine compound; a halogen-free flame retardant; and a curing agent, in which at least one of the epoxy resin and the thermoplastic resin contains a phosphorus-containing resin, and the phosphorus content in the solid portion of the adhesive resin composition is 2.5% by mass or more. Preferably, a phosphorus-containing epoxy resin is used as the epoxy resin, a thermoplastic resin containing 10% to 70% by mass of a phosphorus-containing polyester is used as the thermoplastic resin, and the amount of benzoxazine is 5 to 25 parts by mass and the amount of halogen-free flame retardant is 1 to 30 parts by mass per 100 parts of the resins.

### RELATED APPLICATIONS

This application is the U.S. National Phase under 35 U.S.C. §371 of International Application No. PCT/JP2010/050482, filed on Jan. 18, 2010, which in turn claims the benefit of Japanese Application No. 2009-040558, filed on Feb. 24, 2009, the disclosures of which Applications are incorporated by reference herein.

### TECHNICAL FIELD

The present invention relates to an adhesive resin composition suitable for use in a flexible printed wiring board such as a flexible copper clad laminate, and a laminate and a flexible printed wiring board using the same.

### BACKGROUND ART

In general, flexible printed wiring boards (flexible printed circuit boards) have a basic structure in which a copper foil or the like is bonded with an adhesive to one surface or both surfaces of an insulating film functioning as a base, the insulating film being composed of a heat-resistant film such as a polyimide film. As such an adhesive, hitherto, an adhesive obtained by mixing a flame retardant with a blend resin of a thermosetting resin such as an epoxy resin and a thermoplastic resin such as an acrylic resin, a polyamide, or a polyester resin has been used.

As the flame retardant, halogen flame retardants have been hitherto used because high flame retardancy corresponding to the VTM-0 class or the V-0 class in the Underwriters Laboratories Inc. (UL)-94 standard is required. Recently, however, in view of the problems of environmental pollution, phosphorus flame retardants such as phosphoric acid esters, phosphoric acid ester amides, melamine polyphosphate, ammonium polyphosphate, 9,10-dihydro-9-oxa-10-phosphaphenanthrene-10-oxide and derivatives thereof, and phosphazene compounds have been used instead of the halogen flame retardants.

However, in order to satisfy high flame retardancy corresponding to the VTM-0 class or the V-0 class in the UL-94 standard by using only such a phosphorus flame retardant, it is necessary to mix a large amount of the phosphorus flame retardant as compared with the case where a halogen flame retardant is used. This results in a problem that, with an increase in the amount of phosphorus flame retardant mixed, the adhesiveness decreases.

In order to solve this problem, recently, it has been proposed that the amount of phosphorus flame retardant mixed be reduced by using a resin that utilizes a flame retardant effect of phosphorus.

For example, PTL 1 (Japanese Unexamined Patent Application Publication No. 2003-176470) has proposed that the phosphorus content in a composition is controlled to be 2% by weight or more by using a phosphorus-containing epoxy resin and further using a phosphorus-containing phenoxy resin as a portion of a thermoplastic resin.

In addition, PTL 2 (Japanese Unexamined Patent Application Publication No. 2005-53989) discloses a flame-retardant adhesive resin composition containing a blend resin of a halogen-free epoxy resin and a phosphorus-containing polyester resin, a phosphazene compound functioning as a flame retardant, and inorganic filler such as magnesium hydroxide or aluminum hydroxide. It is described that flame retardancy and solder heat resistance can be satisfied by controlling a content ratio of phosphorus element to the resin component to be in the range of 1.8% to 5% by weight even without using a phosphoric acid ester.

Furthermore, PTL 3 (Japanese Unexamined Patent Application Publication No. 2007-254659) has proposed an adhesive resin composition for a flexible printed wiring board, the adhesive resin composition containing a thermoplastic resin having a solubility parameter of 8 to 16 and, as a flame retardant, a phosphorus-containing polyester resin that has a weight-average molecular weight of 2,000 to 20,000 and that is soluble in an organic solvent. PTL 3 discloses that a sufficient adhesive force can be ensured by using the phosphorus-containing polyester resin having a specific molecular weight without impairing solder heat resistance and flame retardancy, as compared with the case where a phosphoric acid ester flame retardant or a phosphoric acid ester amide flame retardant is used.

Furthermore, PTL 4 (Japanese Unexamined Patent Application Publication No. 2005-248048) has proposed a flame-retardant adhesive composition for a flexible copper clad laminate, the adhesive composition containing a phosphorus-containing epoxy resin as a thermosetting resin, a carboxyl-group-containing polyester resin, a carboxyl-group-containing acrylic resin, or the like as a thermoplastic resin, and phosphorus-containing filler such as phosphoric acid ester amide. It is described that a nitrogen-containing phosphate and a phosphoric acid ester amide can satisfy flame retardancy without decreasing the peel strength, as compared with phosphazenes.

### CITATION LIST

### Patent Literature

PTL 1: Japanese Unexamined Patent Application Publication No. 2003-176470
PTL 2: Japanese Unexamined Patent Application Publication No. 2005-53989
PTL 3: Japanese Unexamined Patent Application Publication No. 2007-254659
PTL 4: Japanese Unexamined Patent Application Publication No. 2005-248048

### SUMMARY OF INVENTION

### Technical Problem

As described above, various halogen-free flame-retardant adhesive resin compositions for a flexible printed wiring board have been proposed. However, the requirement for an adhesive that can highly satisfy adhesiveness, flame retardancy, and solder heat resistance has been continuously increasing, and a further improvement has been desired.

The present invention has been made in view of the above circumstance. An object of the present invention is to provide an adhesive resin composition that is halogen-free and that can satisfy flame retardancy without impairing adhesiveness and solder heat resistance, and a laminate and a flexible printed wiring board using the same. Solution to Problem

Specifically, an adhesive resin composition of the present invention contains an epoxy resin; a thermoplastic resin; a benzoxazine compound; a halogen-free flame retardant; and a curing agent, in which at least one of the epoxy resin and the thermoplastic resin contains phosphorus, and the phosphorus content in the solid portion of the adhesive resin composition is 2.5% by mass or more.

Preferably, the epoxy resin is a phosphorus-containing epoxy resin, the thermoplastic resin contains 10% to 70% by mass of a phosphorus-containing polyester, and the content of the benzoxazine compound is 5 to 25 parts by mass, and the content of the halogen-free flame retardant is 1 to 30 parts by mass per 100 parts by mass of the resins in the adhesive resin composition.

The thermoplastic resin preferably contains a thermoplastic resin having a glass transition temperature of 70° C. or lower, and the thermoplastic resin further preferably contains a polyamide besides the phosphorus-containing polyester.

The benzoxazine compound is preferably a compound having benzoxazine structures at both ends thereof, and the halogen-free flame retardant is preferably a phosphazene.

A laminate of the present invention includes a base film, and an adhesive layer disposed on the base film and composed of the adhesive resin composition of the present invention. A flexible printed wiring board of the present invention includes the laminate of the present invention.

### Advantageous Effects of Invention

The adhesive resin composition of the present invention contains a resin containing phosphorus in its molecule, and a benzoxazine. Consequently, the content of a halogen-free flame retardant, which causes a decrease in adhesiveness, can be reduced, and thus both flame retardancy and adhesiveness can be satisfied.

### DESCRIPTION OF EMBODIMENTS

Embodiments of the present invention will now be described. However, it is to be understood that the embodiments disclosed herein are illustrative in all respects and are not restrictive. It is intended that the scope of the present invention is defined by the description of Claims and includes equivalents of the description in Claims and all modifications within the scope of Claims.

### [Adhesive Resin Composition]

First, an adhesive resin composition of the present invention will be described.

The adhesive resin composition of the present invention contains an epoxy resin; a thermoplastic resin; a benzoxazine; a halogen-free flame retardant; and a curing agent, in which at least one of the epoxy resin and the thermoplastic resin contains phosphorus.

The components will now be described in order.

### (a) Epoxy Resin

The epoxy resin used in the present invention is a resin having at least two epoxy groups in one molecule. Examples thereof include bisphenol A type epoxy resins, bisphenol F type epoxy resins, glycidyl ether type epoxy resins, glycidyl ester type epoxy resins, glycidylamine type epoxy resins, novolac type epoxy resins, and cresol novolac type epoxy resins. Preferably, the epoxy resin used in the present invention is a phosphorus-containing epoxy resin in which a phosphorus atom is bonded to any of these epoxy resins using a reactive phosphorus compound. Such a phosphorus-containing epoxy resin exhibits a flame retardant effect due to phosphorus, and thus the use of the phosphorus-containing epoxy resin can reduce the content of a halogen-free flame retardant.

Examples of the phosphorus-containing epoxy resin include FX289 and FX305 manufactured by Tohto Kasei Co., Ltd., and EPICLON EXA-9710 manufactured by DIC Corporation.

A content ratio between the epoxy resin and the thermoplastic resin (thermoplastic resin:epoxy resin) in the adhesive composition is preferably 3:1 to 1:3.

When the content ratio of the epoxy resin to the thermoplastic resin is too low, the content ratio of the thermoplastic resin in the resin components becomes relatively high and thus heat resistance and a mechanical strength cannot be satisfied. On the other hand, when the content ratio of the epoxy resin is too high, the content ratio of the thermoplastic resin becomes relatively low and thus flexibility decreases and a mechanical strength for bending tends to be insufficient.

### (b) Thermoplastic Resin

Examples of the thermoplastic resin include phosphorus-containing or phosphorus-free polyester resins, acrylic resins, polystyrene resins, polyamide resins, polyamideimide resins, polycarbonate resins, polyphenylene oxide resins, polyphenylene sulfide resins (such as polyphenylene sulfide, polyphenylene sulfide ketone, and polyphenylene sulfide sulfone), polysulfone resins (such as polysulfone and polyethersulfone), polyetherimide resins (such as poly(N-formylethyleneimine) resins), polyetheretherketone resins, polyacetal resins (such as polyoxymethylene resins), and ketone resins (such as aliphatic polyketone resins, acetone formaldehyde resins, furfural acetone resins, and cyclic ketone resins). These thermoplastic resins may be used alone or in combination of two or more resins.

A phosphorus-containing polyester resin is preferably contained in an amount of 10% to 70% by mass, more preferably 20% to 60% by mass, and still more preferably 30% to 50% by mass in the thermoplastic resin. By using such a phosphorus-containing polyester resin as a portion of the thermoplastic resins, it is possible to exhibit a flame retardant effect due to phosphorus and to provide a cured product having good flexibility and suitable for use in a flexible printed wiring board.

The phosphorus-containing polyester resin may be any resin as long as a polyester resin contains a phosphorus atom therein. The phosphorus-containing polyester resin can be synthesized by, for example, the methods described in Japanese Unexamined Patent Application Publication Nos. 2007-254659 and 2002-3588. Commercially available phosphorus-containing polyester resins may also be used. Examples of the commercially available phosphorus-containing polyester resins include VYLON 537 (weight-average molecular weight: 140,000, Tg=4° C.), VYLON 337 (weight-average molecular weight: 27,000, Tg=14° C.), and VYLON 237 (weight-average molecular weight: 30,000, Tg=68° C.), all of which are manufactured by Toyobo Co., Ltd.

As a thermoplastic resin other than the phosphorus-containing polyester, a phosphorus-free thermoplastic resin is preferable and a polyamide resin is more preferable in view of the compatibility with the phosphorus-containing polyester resin and the phosphorus-containing epoxy resin.

The polyamide resin can be synthesized by a reaction of a dicarboxylic acid, a diamine, an aminocarboxylic acid, a lactam, and the like. The reaction is not limited to a reaction between one dicarboxylic acid and one diamine. The polyamide resin may be synthesized by using a plurality of dicarboxylic acids and a plurality of diamines.

Examples of the dicarboxylic acid include terephthalic acid, isophthalic acid, orthophthalic acid, naphthalene dicarboxylic acids (1,5-, 2,5-, 2,6-, and 2,7-isomers), biphenyl dicarboxylic acids (2,2′-, 3,3′-, and 4,4′-isomers), 4,4′-diphenyl ether dicarboxylic acid, 4,4′-diphenyl methane dicarboxylic acid, 4,4′-diphenyl sulfone dicarboxylic acid, 1,2-bis(phenoxy)ethane-4,4′-dicarboxylic acid, anthracenedicarboxylic acid (2,5- and 2,6-isomers), phenylene diacetic acids (o-, m-, and p-isomers), phenylene dipropionic acids (o-, m-, and p-isomers), phenylmalonic acid, phenylglutaric acid, diphenylsuccinic acid, oxalic acid, malonic acid, succinic acid, glutaric acid, adipic acid, sebacic acid, decanedicarboxylic acid, maleic acid, fumaric acid, itaconic acid, 1,3-cyclobutanedicarboxylic acid, 1,3-cyclopentane dicarboxylic acid, 1,4-cyclohexane dicarboxylic acid, 1,2-cyclohexane dicarboxylic acid, 1,3-(dicarboxymethyl)cyclohexane, 1,4-(dicarboxymethyl)cyclohexane, dicyclohexyl-4,4′-dicarboxylic acid, and dimer acids.

Examples of the diamine include hexamethylenediamine, heptamethylenediamine, 1,4-bis(aminomethyl)cyclohexane, bis(p-aminocyclohexyl)methane, m-xylenediamine, 1,4-bis(3-aminopropoxy)cyclohexane, piperazine, and isophorone diamine.

Examples of the aminocarboxylic acid include 11-aminoundecanoic acid, 12-aminododecanoic acid, 4-aminomethylbenzoic acid, 4-aminomethylcyclohexanecarboxylic acid. 7-aminoenanthic acid, and 9-aminononanoic acid.

Examples of the lactam include ε-caprolactam, ω-lauryllactam, α-pyrrolidone, and α-piperidone.

Among these, in particular, polyamides containing a dimer acid as a component are obtained by a common polycondensation of a dimer acid and a diamine. In this case, another dicarboxylic acid other than the dimer acid, such as adipic acid, azelaic acid, or sebacic acid, may be contained as a comonomer.

As the above-described thermoplastic resins, thermoplastic resins having a glass transition temperature of 70° C. or lower are preferably used. This is because if the glass transition temperature is too high, a flexible adhesive layer cannot be obtained, resulting in a decrease in handleability of a laminate such as an adhesive sheet or a coverlay. In addition, such thermoplastic resins having a glass transition temperature of 70° C. or lower are preferable because they are good in terms of reactivity with epoxy resins and flexibility, and they have a low water-absorbing property and are good in terms of solder heat resistance and insulating property.

The adhesive resin composition of the present invention contains the epoxy resin and the thermoplastic resin described above. The epoxy resin and the thermoplastic resin are selected so that at least one of the resins (the epoxy resin and the thermoplastic resin) in the resin composition contains a phosphorus-containing resin (a phosphorus-containing epoxy resin or a phosphorus-containing polyester resin) and the phosphorus content in the resin composition is 2.5% by mass or more, and preferably 2.5% to 4% by mass.

### (c) Benzoxazine Compound

The benzoxazine compound used in the present invention is a condensate of an oxazine and a benzene ring, and is generally synthesized by allowing a phenol, an amine, and formaldehyde to react with each other. The benzoxazine compound may be any compound as long as the compound has a benzoxazine structure. The benzoxazine compound may be a multivalent oxazine compound having a plurality of benzoxazine rings in its molecule. In particular, a compound having benzoxazine structures at both ends thereof is preferably used.

Commercially available benzoxazine compounds may be used. For example, benzoxazines (P-d type, which is a both-end-type benzoxazine, and F-a type, which is a non-end-type benzoxazine) manufactured by Shikoku Chemicals Corporation, BXZ-1 (BS-BXZ), BXZ-2 (BF-BXZ), BXZ-3 (BA-BXZ) manufactured by Konishi Chemical Ind. Co., Ltd., and the like are available. Among these, from the standpoint of heat resistance, flame retardancy, and ease of handling, the P-d type, which has benzoxazine structures at both ends thereof, is preferable.

Such benzoxazine compounds are subjected to ring-opening polymerization by heating and cured to provide cured products having good heat resistance and flame retardancy. Furthermore, the benzoxazine compounds can also react with epoxy resins to form cured products having a high crosslinking density and having good flame retardancy and toughness. In cured products obtained by a reaction with a phosphorus-containing epoxy resin, it is possible to form crosslinked products between the phosphorus-containing epoxy resin and a benzoxazine polymer. Thus, cured products having good flame retardancy can be formed.

The content of the benzoxazine compound in the resin composition is preferably 5 to 25 parts by mass, and more preferably 10 to 20 parts by mass per 100 parts by mass of the resin components in the resin composition. When the content of the benzoxazine compound exceeds 25 parts by mass, the resulting cured product becomes too hard, adhesiveness tends to decrease, and solder heat resistance also tends to decrease.

### (d) Halogen-Free Flame Retardant

The halogen-free flame retardant used herein is not particularly limited, and halogen-free flame retardants that are generally used as flame retardants can be used. Specifically, for example, phosphorus compounds such as phosphoric acid esters, phosphoric acid ester amides, phosphazenes, and 9,10-dihydro-9-oxa-10-phosphaphenanthrene-10-oxide; and metal hydroxides such as magnesium hydroxide and aluminum hydroxide can be used. Among these, phosphazenes are preferably used from the standpoint of the phosphorus concentration and the solubility in a solvent.

The term “phosphazenes” is a popular name of a group of compounds having a double bond and containing phosphorus and nitrogen as constituent elements. The phosphazene is not particularly limited as long as the compound has a phosphazene structure in its molecule. The phosphazene may be a cyclophosphazene having a cyclic structure, a linear polymer or oligomer obtained by conducting ring-opening polymerization of the cyclophosphazene.

The amount of halogen-free flame retardant is 1 to 30 parts by mass, preferably 10 to 20 parts by mass per 100 parts by mass of the resins components corresponding to the total amount of the epoxy resin and the thermoplastic resin. According to the adhesive resin composition of the present invention, at least one of the epoxy resin and the thermoplastic resin contains a phosphorus-containing resin, the adhesive resin composition is prepared so that the phosphorus content in the solid portion of the resin composition is 2.5% by mass or more, and a benzoxazine compound capable of forming a cured product having good flame retardancy is further mixed in the resin composition. Accordingly, when the halogen-free flame retardant is additionally added in an amount of only about 1 part by mass per 100 parts by mass of the resin components, desired flame retardancy can be ensured. On the other hand, with an increase in the content of the halogen-free flame retardant, the adhesiveness decreases. Therefore, it is necessary to control the content of the halogen-free flame retardant to be 30 parts by mass or less at a maximum per 100 parts by mass of the resin components.

When a phosphorus compound is used as the halogen-free flame retardant, the phosphorus content in the solid portion of the resin composition is controlled to be 2.5% by mass or more, preferably 2.5% to 4% by mass in combination with the content of phosphorus contained in the phosphorus-containing epoxy resin, the phosphorus-containing polyester, and another phosphorus-containing resin if the other resin contains phosphorus.

### (e) Curing Agent

The curing agent may be a compound that is generally used as a curing agent of an epoxy resin. Examples of the curing agent include polyamine curing agents, acid anhydride curing agents, boron trifluoride-amine complex salts, imidazole curing agents, aromatic diamine curing agents, carboxylic acid curing agents, and phenol resins.

Examples of the polyamine curing agents include aliphatic amine curing agents such as diethylenetriamine and tetraethylene tetramine; alicyclic amine curing agents such as isophorone diamine; aromatic amine curing agents such as diaminodiphenylmethane and phenylenediamine; and dicyandiamide. Examples of the acid anhydride curing agents include phthalic anhydride, pyromellitic dianhydride, trimellitic anhydride, and hexahydrophthalic anhydride.

The amount of curing agent mixed is appropriately determined in accordance with the epoxy equivalent of the epoxy resin.

### [Preparation of Adhesive Resin Composition]

The adhesive resin composition of the present invention is prepared by mixing the components (a) to (e) described above so that the phosphorus content in the adhesive resin composition is 2.5% by mass or more, and preferably 2.5% to 4% by mass. The reason for this is as follows. Although the amount of flame retardant mixed can be reduced by incorporating the benzoxazine compound, flame retardancy is insufficient when the phosphorus content in the composition is less than 2.5% by mass. On the other hand, by incorporating the benzoxazine compound, flame retardancy can be satisfied even at a phosphorus content of 4% by mass in the composition.

The adhesive resin composition of the present invention is prepared by further blending and mixing a hardening accelerator, a silane coupling agent, a leveling agent, a defoaming agent, inorganic filler, and the like, as required, in addition to the components (a) to (e).

The adhesive resin composition of the present invention is usually dissolved in an organic solvent, and used as an adhesive solution. Examples of the organic solvent that can be used include toluene, methanol, ethanol, isopropanol, acetone, dioxolane, hexane, triethylamine, isobutyl acetate, butyl acetate, ethyl acetate, methyl acetate, methyl ethyl ketone (MEK), methyl isobutyl ketone, Cellosolve, ethylene glycol, dimethylformamide (DMF), xylene, and N-methylpyrrolidone.

### [Applications]

The adhesive resin composition of the present invention having the constitution described above is good in terms of solder heat resistance, satisfies flame retardancy of the V-0 class or the VTM-0 class in the UL-94 standard, and is good in terms of adhesiveness and flexibility. Accordingly, the adhesive resin composition of the present invention can be suitably used for an adhesive layer of a laminate such as a three-layer substrate, an adhesive sheet, or a coverlay, or a flexible printed wiring board.

The flexible printed wiring board is produced by bonding an insulating film to a metal foil with a cured product of the adhesive resin composition of the present invention therebetween so as to include a plurality of layers. Specifically, a flexible printed wiring board can be formed by stacking a product (so-called three-layer substrate) prepared by applying the adhesive resin composition of the present invention onto an insulating film, drying the adhesive resin composition (to a semi-cured state), further stacking a metal foil, and then curing by heating; a product (so-called coverlay) prepared by applying the adhesive resin composition of the present invention onto an insulating film, drying the adhesive resin composition (to a semi-cured state), and covering an exposed surface of the resulting adhesive layer with an insulating film called separator; a product (so-called adhesive sheet) prepared by applying the adhesive resin composition of the present invention onto a separator or a base film, drying the adhesive resin composition (to a semi-cured state), and covering an exposed surface with a separator; and the like, and curing the resulting laminate by heating. Note that the separator is removed when the products are stacked.

Herein, “semi-cured state” refers to a state in which an adhesive resin composition has adhesiveness. The semi-cured state is formed by heating the adhesive resin composition of the present invention, for example, at 100° C. to 180° C. for two minutes. “Heat-cured state” is formed by heating an adhesive layer in the semi-cured state, for example, at 140° C. to 180° C. for 10 minutes to several hours, and further applying a pressure as required, and refers to a state in which a thermosetting resin (epoxy resin) is cured by a reaction with a curing agent under heating. A suitable heating time varies depending on the components and the application (for example, a substrate, a coverlay, a bonding film, or the like) of the adhesive.

It is sufficient that the three-layer substrate of the present invention includes an insulating film and a metal foil bonded to at least one surface of the insulating film. The three-layer substrate may have a three-layer structure (so-called three-layer single-sided substrate) including an insulating film, an adhesive layer, and a metal foil layer.

Alternatively, the three-layer substrate may have a five-layer structure (so-called three-layer double-sided substrate) including a metal foil, an adhesive layer, an electrically insulating film, an adhesive layer, and a metal foil layer.

Examples of the insulating film include a polyimide film, a polyester film, a polyetheretherketone film, and a polyphenylene sulfide film.

Examples of the metal foil include a copper foil and an aluminum foil. A copper foil is preferably used.

A coverlay film is a laminate used as a material that covers a surface of a flexible copper clad laminate, on which a wiring pattern is formed by processing a copper foil of the flexible copper clad laminate, so that the material protects the wiring. The coverlay film includes an insulating film and an adhesive layer in the semi-cured state, the adhesive layer being composed of the adhesive resin composition of the present invention and provided on the insulating film. A separator having a releasing property is usually bonded onto the adhesive layer.

The adhesive sheet includes a separator or a base film in some cases and an adhesive layer in a semi-cured state, the adhesive layer being composed of the adhesive resin composition of the present invention and provided on the separator or the base film, and is used for lamination of substrates and bonding of a reinforcing plate. The base film is selected in accordance with the application, and may be a heat-resistant, insulating film such as a polyimide film, or a prepreg sheet including a glassfiber reinforced plastic sheet, a nonwoven fabric or the like as a base.

### EXAMPLES

Best modes for carrying out the present invention will now be described by way of Examples. The Examples do not limit the scope of the present invention.

### [Measurement and Evaluation Methods]

First, evaluation methods conducted in Examples will be described.

### (1) Adhesiveness

A peel strength (N/cm) was measured by drawing the copper foil side to peel off a copper foil from a polyimide film at 23° C. in accordance with JIS C 6481.

### (2) Solder Heat Resistance

A test was conducted under the following conditions in accordance with JIS C 6471.
Temperature of solder bath: 280° C.
Immersion time: 60 seconds

The presence or absence of an abnormal appearance such as swelling of an adhesive layer was evaluated by visual observation. According to the results, when no abnormal appearance such as swelling was observed, the sample was denoted as “O”. When an abnormal appearance such as swelling or peeling was observed, the sample was denoted as “X”.

### (3) Flame Retardancy

An evaluation test of flame retardancy was conducted in accordance with UL-94. A sample that passed the above standard (V-0 class) was denoted as “O”, and a sample that did not pass the standard was denoted as “X”.

### [Preparation of Adhesive Resin Compositions]

An epoxy resin, a thermoplastic resin (polyester and polyamide), a benzoxazine compound, a halogen-free flame retardant (phosphazene), and a curing agent were mixed in amounts shown in Table to prepare resin compositions.

The prepared resin compositions were each dissolved and dispersed under stirring in a solvent containing methyl ethyl ketone and dimethylformamide to prepare adhesive solution Nos. 1 to 8 for a flexible printed wiring board, the adhesive solutions each having a solid content concentration of 30% by weight.

As the epoxy resin, FX289 (phosphorus-containing epoxy resin) or YD011 (phosphorus-free epoxy resin) manufactured by Tohto Kasei Co., Ltd. was used. As the polyester, VYLON 337 (phosphorus-containing polyester, weight-average molecular weight: 27,000, Tg=14° C.), VYLON 237 (phosphorus-containing polyester, weight-average molecular weight: 30,000, Tg=68° C.), or VYLON 300 (phosphorus-free polyester, weight-average molecular weight: 23,000, Tg=7° C.) manufactured by Toyobo Co., Ltd. was used. As the benzoxazine compound, a benzoxazine (P-d type) manufactured by Shikoku Chemicals Corporation was used. As the halogen-free flame retardant (phosphazene), SPB100 manufactured by Otsuka Chemical Co., Ltd. was used. As the curing agent, trimellitic anhydride manufactured by Mitsubishi Gas Chemical Company, Inc. was used.

Each of the adhesive solutions was applied onto a surface of a polyimide film having a thickness of 25 μm so that the thickness of the adhesive after drying was 20 μm. The adhesive solution was dried at 150° C. for two minutes to form an adhesive layer in a semi-cured state. This adhesive layer in the semi-cured state was laminated with a rolled copper foil having a thickness of 18 μm, and the resulting laminate was then heated by hot pressing at a pressure of 3 MPa at 160° C. for 40 minutes. Thus, flexible printed wiring boards were prepared.

For the prepared flexible printed wiring boards, the adhesiveness and solder heat resistance were measured and evaluated on the basis of the evaluation methods described above. For the evaluation of flame retardancy, samples were prepared without being laminated with the copper foil, and were then heated at 160° C. for 40 minutes without applying a pressure. These samples were used for the evaluation of flame retardancy. Table shows the results.

TABLE

| | | No. | | | | | | | |
|---|---|---|---|---|---|---|---|---|---|
| | | 1 | 2 | 3 | 4 | 5 | 6 | 7 | 8 |
| Composition (parts) | Phosphorus-containing epoxy resin | 25 | 25 | 25 | 25 | 0 | 25 | 25 | 25 |
| | Phosphorus-free epoxy resin | 0 | 0 | 0 | 0 | 25 | 0 | 0 | 0 |
| | Polyamide | 30 | 30 | 30 | 30 | 30 | 30 | 30 | 30 |
| | Phosphorus-containing polyester 1 | 20 | 20 | 20 | 0 | 20 | 20 | 20 | 0 |
| | Phosphorus-containing polyester 2 | 0 | 0 | 0 | 0 | 0 | 0 | 0 | 20 |
| | Phosphorus-free polyester | 0 | 0 | 0 | 20 | 0 | 0 | 0 | 0 |
| | Benzoxazine | 10 | 15 | 20 | 10 | 10 | 0 | 0 | 10 |
| | Phosphazene | 15 | 15 | 15 | 15 | 15 | 20 | 30 | 15 |
| | Curing agent | 5 | 5 | 5 | 5 | 5 | 5 | 5 | 5 |
| Content in | Phosphorus | 2.9 | 2.8 | 2.7 | 2.4 | 2.4 | 3.7 | 4.6 | 2.9 |
| composition (%) | Benzoxazine | 9.5 | 13.6 | 17.4 | 9.5 | 9.5 | 0 | 0 | 9.5 |
| | Phosphazene | 14.3 | 13.6 | 13.0 | 14.3 | 14.3 | 20.0 | 27.3 | 14.3 |
| Content per 100 | Benzoxazine | 13.3 | 20.0 | 26.7 | 13.3 | 13.3 | 0 | 0 | 13.3 |
| parts of resin (parts) | Phosphazene | 20 | 20 | 20 | 20 | 20 | 26.7 | 40 | 20 |
| Evaluations | Adhesiveness (N/cm) | 8 | 5.8 | 4.3 | 8.3 | 8.7 | 3.8 | <3 | 7.2 |
| | Solder heat resistance | ∘ | ∘ | x | ∘ | ∘ | ∘ | x | ∘ |
| | Flame retardancy | ∘ | ∘ | ∘ | x | x | x | ∘ | ∘ |

Phosphorus-containing polyester 1: VYLON 337 manufactured by Toyobo Co., Ltd.
Phosphorus-containing polyester 2: VYLON 237 manufactured by Toyobo Co., Ltd.

Nos. 1 to 3 are resin compositions which contain the benzoxazine and in which the phosphorus content in the compositions is adjusted to be 2.5% or more by using the phosphorus-containing epoxy resin and the phosphorus-containing polyester, and correspond to Examples. All the resin compositions could satisfy flame retardancy while maintaining high adhesiveness. However, in No. 3, since the content of the benzoxazine exceeded 25 parts by mass per 100 parts by mass of the resin components (total amount of the thermoplastic resins and the epoxy resin), No. 3 did not pass the solder heat resistance. These results show that, in order to satisfy flame retardancy, adhesiveness, and solder heat resistance, it is preferable to control the phosphorus content in the composition to be 2.5% by mass or more and to control the content of the benzoxazine to be 5 to 25 parts by mass per 100 parts by mass of the resin components.

Nos. 6 and 7 are resin compositions in which the phosphorus content in the compositions is adjusted to be 2.5% by mass or more by using the phosphorus-containing epoxy resin and the phosphorus-containing polyester but which contain no benzoxazine, and correspond to Comparative Examples. In No. 6, even though the content of the flame retardant (phosphazene) was increased by 30%, as compared with that in No. 1, flame retardancy could not be satisfied. In No. 7, although flame retardancy could be satisfied by increasing the content of phosphazene to double the content of phosphazene in No. 1, No. 7 did not pass the solder heat resistance. In addition, since a large amount of flame retardant was mixed in Nos. 6 and 7, the adhesiveness significantly decreased, and thus Nos. 6 and 7 could not be used as flexible printed wiring boards. These results show that the use of a benzoxazine compound is useful for obtaining both satisfactory flame retardancy and adhesiveness.

Nos. 4 and 5 are cases where the resin compositions contain the benzoxazine but the phosphorus content in the compositions is less than 2.5% by mass. Although the content of the benzoxazine to the resin components was the same as that of No. 1, flame retardancy could not be satisfied. These results show that, in order to satisfy flame retardancy, it is necessary to control the phosphorus content in the compositions to be 2.5% by mass or more by incorporating the benzoxazine compound, and the phosphorus-containing polyester and/or the phosphorus-containing epoxy resin, i.e., to use these components in combination.

No. 8 is a composition having the same composition as No. 1 except that the phosphorus-containing polyester having a glass transition temperature of 68° C. was used. Flame retardancy, adhesiveness, and solder heat resistance could be satisfied as in No. 1.

### INDUSTRIAL APPLICABILITY

The adhesive resin composition of the present invention is halogen-free, has good flexibility, and has good adhesiveness and flame retardancy. Accordingly, the adhesive resin composition of the present invention is suitable for use in an adhesive layer of a flexible printed wiring board.

1. An adhesive resin composition comprising an epoxy resin; a thermoplastic resin; a benzoxazine compound; a halogen-free flame retardant; and a curing agent,
wherein at least one of the epoxy resin and the thermoplastic resin contains phosphorus, and
the phosphorus content in the solid portion of the adhesive resin composition is 2.5% by mass or more.

2. The adhesive resin composition according to claim 1,
wherein the epoxy resin is a phosphorus-containing epoxy resin,
the thermoplastic resin contains 10% to 70% by mass of a phosphorus-containing polyester, and
the content of the benzoxazine compound is 5 to 25 parts by mass, and the content of the halogen-free flame retardant is 1 to 30 parts by mass per 100 parts by mass of the resins in the adhesive resin composition.

3. The adhesive resin composition according to claim 1, wherein the benzoxazine compound is a compound having benzoxazine structures at both ends thereof.

4. The adhesive resin composition according to claim 1, wherein the halogen-free flame retardant is a phosphazene.

5. The adhesive resin composition according to claim 1, wherein the thermoplastic resin contains a thermoplastic resin having a glass transition temperature of 70° C. or lower.

6. The adhesive resin composition according to claim 2, wherein the thermoplastic resin further contains a polyamide besides the phosphorus-containing polyester.

7. A laminate comprising a base film; and an adhesive layer disposed on the base film and composed of the adhesive resin composition according to claim 1.

8. A flexible printed wiring board comprising the laminate according to claim 7.
